(19) United States
(12) Patent Application Publication
(10) Pub. No.: US 2026/0065957 A1
(43) Pub. Date: Mar. 5, 2026

(54) VEHICLE CONTROL DEVICE, STORAGE DEVICE AND VEHICLE SYSTEM

(71) Applicant: SAMSUNG ELECTRONICS CO., LTD., Suwon-si (KR)

(72) Inventors: Jinwook Lee, Suwon-si (KR); Seungcheol Lee, Suwon-si (KR); Seohyun Shin, Suwon-si (KR)

(21) Appl. No.: 19/077,961

(22) Filed: Mar. 12, 2025

(30) Foreign Application Priority Data
Aug. 28, 2024 (KR) 10-2024-0115990

(51) Int. Cl. G11C 7/04; G11C 11/406

(52) U.S. Cl. CPC G11C 7/04; G11C 11/40626; G11C 2207/2227

(57) ABSTRACT

A vehicle control device includes a memory configured to store a vehicle control program; and a processor configured to execute the vehicle control program to: in response to a detection of operation termination of a vehicle, receive an initial retention expected period from a storage device of the vehicle; detect a period condition or a temperature condition before the initial retention expected period has elapsed after a power-off request for the storage device is provided; provide a power-on request to the storage device in response to residual capacity of a battery of the vehicle being equal to or exceeding a threshold level; control the storage device to determine a state of a memory cell; receive an updated retention expected period based on the state of the memory cell from the storage device; and selectively provide a refresh request to the storage device based on the updated retention expected period.

### CROSS-REFERENCE TO RELATED APPLICATION(S)

This application claims benefit of priority to Korean Patent Application No. 10-2024-0115990 filed on Aug. 28, 2024, in the Korean Intellectual Property Office, the disclosure of which is incorporated herein by reference in its entirety.

### BACKGROUND

Recently, in the automobile industry, various devices or systems have been developed to provide driving convenience for users. For example, an automobile electrical system may provide autonomous driving or various user experiences. An automobile electrical system may provide driving convenience or various infotainment through semiconductor integrated circuits.

An electric vehicle has been required to employ a high-capacity storage device to store various data related to an automobile electrical system. Due to electrical properties of a storage device, when data is left in a programmed state, it may be difficult to retain the data stored therein. Since the storage device may be left in a powered-off state due to circumstances such as long-term parking of an electric vehicle, a measure for retaining the data of the storage device may be desired.

### SUMMARY

An example implementation of the present disclosure is to provide a vehicle control device, a storage device and a vehicle system which may reduce power consumption of a battery of a vehicle while the vehicle is not in operation and may control a refresh operation of a storage device in a timely manner to retain data in the storage device.

According to an example implementation of the present disclosure, a vehicle control device includes a memory configured to store a vehicle control program; and a processor configured to execute the vehicle control program, wherein, in response to a detection of operation termination of a vehicle, the processor is configured to receive an initial retention expected period from a storage device of the vehicle, to provide a power-off request to the storage device, to detect a period condition or a temperature condition before the initial retention expected period has elapsed after the power-off request is provided, to provide a power-on request to the storage device in response to residual capacity of a battery of the vehicle being equal to or exceeding a threshold level, to control the storage device to determine a state of a memory cell of a predetermined memory region, to receive an updated retention expected period based on the state of the memory cell from the storage device, and to selectively provide a refresh request to the storage device based on the updated retention expected period.

According to an example implementation of the present disclosure, a storage device includes a memory device configured to store data of a vehicle; and a controller configured to control the memory device, wherein the controller is configured to determine an initial retention expected period based on a first temperature of the storage device at an operation termination time point of the vehicle in response to a retention expected period request, to provide the first temperature and the initial retention expected period to a vehicle control device, to perform a power-off operation in response to a power-off request, to perform an initialization operation in response to a power-on request, to perform a read operation on a predetermined memory region in response to an update request for a retention expected period, to determine a state of a memory cell of the storage device based on a result of the read operation, to determine an updated retention expected period based on the determined state of the memory cell and a temperature of the storage device, and to selectively perform a refresh operation based on the updated retention expected period.

According to an example implementation of the present disclosure, a vehicle system includes a storage device configured to store vehicle data; and a vehicle control device configured to execute a vehicle control program, wherein the vehicle control device is configured to detect a parking position in response to vehicle operation being terminated, in response to long-term parking of the vehicle being predicted based on the parking position to receive an initial retention expected period that is determined based on a temperature of the storage device from a storage device mounted on the vehicle, to provide a first power-off request for a retention mode to the storage device, to detect a period condition or a temperature condition before the retention expected period has elapsed after the power-off request is provided, and to provide a power-on request to the storage device in response to a detection of the period condition or the temperature condition, and wherein the storage device is configured to control a read operation of a predetermined memory region in response to power being supplied and the retention mode being detected, and to provide an updated retention expected period that is determined based on a cell state and a temperature of the storage device, the cell state being determined by the read operation from the storage device.

The vehicle control device may provide the power-on request to the storage device after a predetermined period has elapsed after the second power-off request is provided, and provide a third power-off request for the retention mode after providing the power-on request.

The vehicle control device may determine whether the vehicle is long-term parked based on the parking position and information input from a user terminal.

The vehicle control device may determine parking time at the parking position, and determine whether the vehicle is long-term parked based on the determined parking time at the parking position.

### BRIEF DESCRIPTION OF DRAWINGS

The above and other aspects, features, and advantages of the present disclosure will be more clearly understood from the following detailed description, taken in combination with the accompanying drawings, in which:

FIGS. 1 and 2 are block diagrams illustrating an example of vehicle system according to an example implementation of the present disclosure;

FIG. 3 is a diagram illustrating an example of storage device according to an example implementation of the present disclosure;

FIG. 4 is a diagram illustrating an example of memory device according to an example implementation of the present disclosure;

FIG. 5 is a diagram illustrating an example of distribution of threshold voltage of memory cells according to an example implementation of the present disclosure;

FIG. 6 is a diagram illustrating an example of interaction between a vehicle control device and a storage device according to an example implementation of the present disclosure;

FIG. 7 is a diagram illustrating an example of operation of a vehicle control device according to an example implementation of the present disclosure;

FIG. 8 is a diagram illustrating an example of a data retention period depending on a temperature according to an example implementation of the present disclosure;

FIG. 9 is a diagram illustrating an example of operation of a storage device according to an example implementation of the present disclosure;

FIG. 10 is a diagram illustrating an example of a memory cell state checking method according to an example implementation of the present disclosure;

FIG. 11 is a diagram illustrating an example of a retention period updating method according to an example implementation of the present disclosure;

FIG. 12 is a diagram illustrating an example of a temperature of a vehicle depending on a power-off period of a storage device according to an example implementation of the present disclosure;

FIG. 13 is a diagram illustrating an example of operation of a storage device according to an example implementation of the present disclosure; and

FIG. 14 is a diagram illustrating an example of operation of a vehicle control device according to an example implementation of the present disclosure.

### DETAILED DESCRIPTION

Hereinafter, implementations of the present disclosure will be described as below with reference to the accompanying drawings.

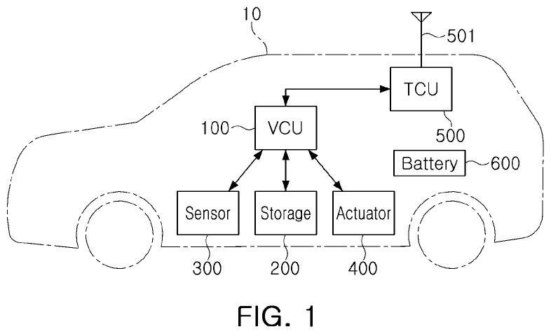

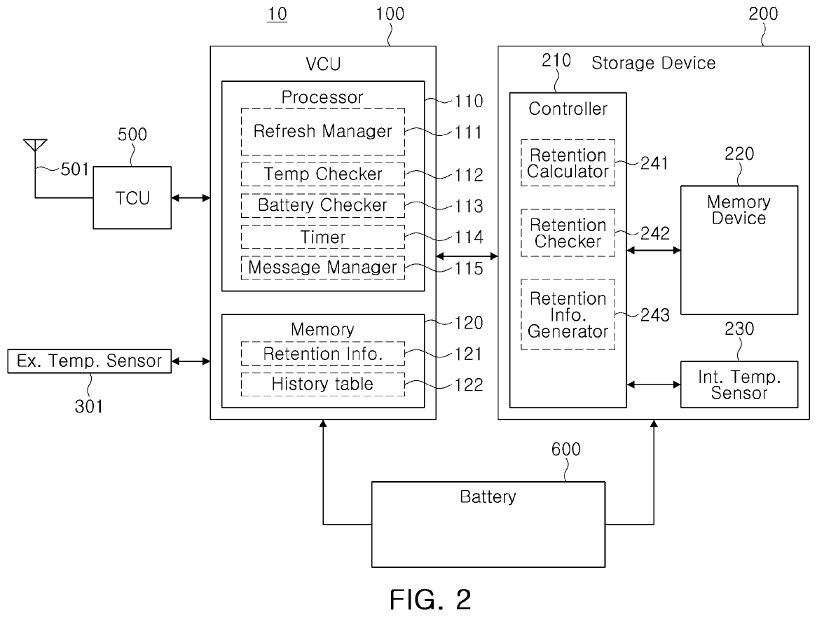

FIGS. 1 and 2 are block diagrams illustrating a vehicle system according to an example implementation.

Referring to FIG. 1, a vehicle system 10 may include a vehicle control unit (VCU) 100, a storage device 200, a sensor 300, an actuator 400, a telematics control unit (TCU) 500, and a battery 600. In an example implementation, the vehicle system 10 may further include an advanced driver assistance system (ADAS) and an infotainment system.

The vehicle control unit 100 may be electrically, mechanically, and communicationally connected to the sensor 300 and the actuator 400 included in the vehicle system 10, and may control operation of at least one device based on a command to perform a function. For example, the vehicle control unit 100 may sense internal and external circumstances of the vehicle using the sensor 300, and may control the actuator 400 based on the sensing results, thereby driving the vehicle. In an example implementation, the vehicle control unit 100 may include zonal vehicle control units configured to control sensors and actuators included in a plurality of zones of the vehicle, and a central vehicle control unit configured to control the zonal vehicle control units.

The storage device 200 may store data obtained from the vehicle control unit 100 and may provide the stored data to the vehicle control unit 100. For example, the vehicle control unit 100 may provide data generated by the sensor 300 and data reprocessed from the data to the storage device 200. The vehicle control unit 100 may obtain data stored in the storage device 200 and may control the actuator 400 based on the obtained data.

The sensor 300 may include various sensors, such as a temperature sensor, an image sensor, a position sensor, a velocity sensor, a pressure sensor, and an inertial sensor. The actuator 400 may include various actuators such as a throttle actuator, a fuel injection device actuator, a brake actuator, a transmission actuator, a steering actuator, a suspension actuator, a window actuator, and a wiper actuator.

The telematics control unit 500 may support communication between the vehicle control unit 100 and an external entity. For example, the telematics control unit 500 may perform communication between an external server and a user terminal by wireless communication through an antenna 501. Wireless communication between the telematics control unit 500 and the server may be performed through various wireless communication methods such as global system for mobile communication (GSM), code division multiple access (CDMA), wideband code division multiple access (WCDMA), universal mobile telecommunications system (UMTS), time division multiple access (TDMA), long term evolution (LTE), NR (new radio) in addition to global positioning system (GPS), global navigation satellite system (GLONASS), Wi-Fi module, wireless broadband module.

The battery 600 may supply power to the vehicle system 10. For example, the battery 600 may include a battery pack and a battery management system which manages the battery pack.

As autonomous driving technique of a vehicle develops, a vehicle may have dozens or more sensors 300 and actuators 400, and vehicle functions have been more complex. The vehicle control unit 100 may process a large amount of data, and the vehicle system 10 may require a high-capacity storage device 200 which may store a large amount of data.

To improve stability of the vehicle system 10, it may be desirable for the data stored in the storage device 200 to be retained without being lost. However, depending on electrical properties of the memory device included in the storage device 200, when the data is left for a long time after being programmed in the memory device, the data may be lost. Particularly, the data retention period may become shorter when the memory device includes memory cells such as quadruple level cell (QLC) in which multiple data bits are stored in a single memory cell, and when the memory device is exposed to high temperature.

Similarly to a server system in which power is continuously supplied to the storage device, the storage device may periodically perform a refresh operation in which the storage device reads the programmed data, may correct errors in the read data by performing an error correction code (ECC) decoding, and a refresh operation of reprograming the data with the corrected errors may be performed periodically. However, differently from the server system, in the case of the vehicle system 10, the power supply to the storage device 200 may be terminated when the vehicle operation is terminated.

When the vehicle control unit 100 may supply power to the storage device 200 and may request a refresh operation based on a uniform reference, it may be difficult to perform the refresh operation on the storage device 200 in a timely manner. For example, when the refresh operation is performed infrequently, it may be difficult to retain the data stored in the storage device 200, and conversely, when the refresh operation is performed frequently, the storage device 200 may consume excessive power from the battery 600.

According to an example implementation, the vehicle control unit 100 may obtain a retention expected period based on a temperature of a present time point from the storage device 200 before requesting powering off to the storage device 200 when operation of the vehicle is terminated. The vehicle control unit 100 may supply power to the storage device 200 before the retention expected period elapses, may obtain an updated retention expected period based on a state of an actual memory cell of the storage device 200, and may selectively control a refresh operation of the storage device 200 based on the updated retention expected period.

The retention expected period may refer to a limit period during which data stored in the storage device 200 is expected to be retained without being lost. For example, the retention expected period may be defined as a period during which an error in data read from the memory device may be retained to a degree to which the error may be corrected by an ECC decoder.

Referring to FIG. 2, the vehicle system 10 may include a vehicle control unit 100, a storage device 200, a telematics control unit 500, a battery 600, and an external temperature sensor 301. The vehicle control unit 100, the storage device 200, the telematics control unit 500, and the battery 600 in FIG. 2 may correspond to examples described with reference to FIG. 1. The external temperature sensor 301 may be included in the sensor 300 described with reference to FIG. 1.

The vehicle control unit 100 may include a processor 110 and a memory 120. The processor 110 may execute a vehicle control program and may control the vehicle system 10. The memory 120 may store the vehicle control program and vehicle management data. In an example implementation, the vehicle control program and the vehicle management data may be loaded from the storage device 200.

According to an example implementation, the processor 110 may execute at least a refresh manager 111, a temperature checker 112, a battery checker 113, a timer 114, and a message manager 115. The memory 120 may store programs for executing the refresh manager 111, the temperature checker 112, the battery checker 113, the timer 114, and the message manager 115, and may store retention information 121 and a history table 122.

The retention information 121 may be information received from the storage device 200 before the storage device 200 is powered off. For example, the retention information 121 may include a temperature and a retention expected period of the operation termination time point of the storage device 200. In an example implementation, the retention information 121 may further include a usage rate, a program/erase (P/E) cycle, and firmware version information of the storage device 200.

The refresh manager 111 may determine a power-on time point of the storage device 200 by referring to the retention information 121 after the storage device 200 is powered off, and may provide a power-on request to the storage device 200.

According to an example implementation, the refresh manager 111 may sense a period condition or a temperature condition before the retention expected period elapses from the power-off time point of the storage device 200, and may request the storage device 200 to check a state of a memory cell and to provide an updated retention expected period based on the state of the memory cell. The power-off time point of the storage device 200 can be the moment at which the storage device is powered off. When the retention expected period is updated in the retention information 121, the refresh manager 111 may provide a refresh request or a power-off request to the storage device 200 based on the updated retention expected period.

The temperature checker 112 may check an external temperature of the storage device 200 using the external temperature sensor 301 and may provide the checked temperature to the refresh manager 111.

The battery checker 113 may check the state of the battery 600 and may provide battery state information to the refresh manager 111. For example, the state of the battery 600 may include residual capacity of the battery 600.

The timer 114 may generate present time-point information. For example, the timer 114 may provide present time-point information to the refresh manager 111 at the power-off time point of the storage device 200.

The message manager 115 may generate a message to be provided to an external entity of the vehicle system 10 and may provide the message to the telematics control unit 500. For example, the message manager 115 may generate a message to provide battery state information and retention information of the storage device 200 to a user terminal.

The history table 122 may store a history of the refresh operation performed in the storage device 200. For example, the history table 122 may store the period taken for the refresh operation, and the amount of battery power consumed due to the refresh operation. In an example implementation, the information stored in the history table 112 may be collected from an external server and may be used for analysis and management of the vehicle system 10.

The storage device 200 may include a controller 210, a memory device 220, and an internal temperature sensor 230. The memory device 220 may store vehicle management data, and the internal temperature sensor 230 may measure the temperature in the storage device 200. The controller 210 may control the memory device 220 and the internal temperature sensor 230. For example, the controller 210 may include a processor and a memory, and may execute a program for controlling the storage device.

According to an example implementation, the controller 210 may execute the retention calculator 241, the retention checker 242, and the retention information generator 243.

The retention calculator 241 may receive the present temperature from the internal temperature sensor 230 at the operation termination time point of the storage device 200, and may calculate the retention expected period based on the present temperature.

The retention period of the data stored in the memory device 220 may be varied greatly depending on the temperature. Specifically, according to the Arrhenius equation indicating the temperature dependence of the reaction rate, the retention period may be exponentially shortened as the temperature increases. The retention calculator 241 may determine an initial retention expected period at the present temperature based on a relationship model between the reference retention period, the present temperature, and the retention period according to the temperature, experimentally determined at the test temperature.

The retention checker 242 may control the memory device 220 to read data of a predetermined region in response to a request from the vehicle control unit 100, and may check the actual retention state of memory cells included in the memory device 220 based on the read data.

For example, the retention checker 242 may check the actual retention state by counting the number of error bits of the read data or counting the number of memory cells falling in a predetermined threshold voltage range based on the read data. The retention checker 242 may generate an updated retention expected period based on the retention state and the temperature of the storage device 200.

The retention information generator 243 may generate retention information including the temperature of the operation termination time point of the storage device 200 and the retention expected period to be provided to the vehicle control unit 100.

When the operation of the vehicle is terminated, the storage device 200 may be powered off, and the power supply to the vehicle control unit 100 may be retained. For example, during a period in which operation of the vehicle is terminated, the vehicle control unit 100 may execute at least a portion of programs for vehicle control, such as a refresh manager 111, a temperature checker 112, a battery checker 113, a timer 114, and a message manager 115.

According to an example implementation, when operation of the vehicle is terminated, the vehicle control unit 100 may receive retention information, including a retention expected period, before the storage device 200 is powered off, and may retain the storage device 200 in a powered-off state until a period condition or a temperature condition determined based on the retention information is sensed. Accordingly, the power consumption of the battery 600 may be reduced.

When the period condition and the temperature condition are sensed, the vehicle control unit 100 may supply power to the storage device 200, may receive an updated retention expected period based on the result of checking a state of a memory cell of the storage device 200, and may provide a refresh request to the storage device 200 or may provide a power-off request based on the updated retention expected period.

The vehicle control unit 100 may control the refresh operation of the storage device 200 in a timely manner by reflecting the temperature history actually experienced by the storage device 200 during the powered-off period. Accordingly, the vehicle control unit 100 may retain the data stored in the storage device 200 while preventing unnecessary power consumption of the battery 600.

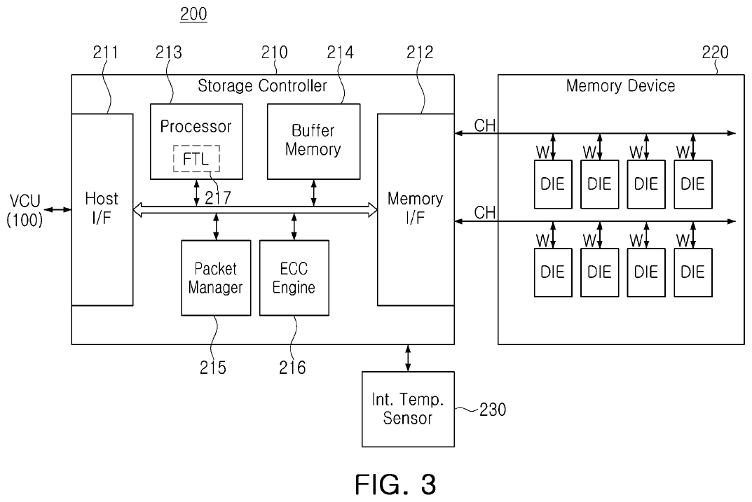

Hereinafter, a vehicle system according to an example implementation may be described in detail with reference to FIGS. 3 to 14.

FIG. 3 is a diagram illustrating a storage device according to an example implementation.

The storage device 200 may include storage media for storing data in response to a request of the vehicle control unit 100.

The storage device 200 may include at least one of a solid state drive (SSD), an embedded memory, and a removable external memory. When the storage device 200 is an SSD, the storage device 200 may comply with the non-volatile memory express (NVMe) standard.

When the memory device 220 of the storage device 200 includes flash memory, the flash memory may include a 2D NAND memory array or a 3D (or vertical) NAND (VNAND) memory array. As another example, the storage device 200 may include other various types of nonvolatile memories. For example, the storage device 200 may be applied with magnetic RAM (MRAM), spin-transfer torque MRAM (CBRAM), ferroelectric RAM (FeRAM), phase RAM (PRAM), resistive RAM, and other various types of memories.

The memory device 220 may include a plurality of memory dies DIE. Each of the plurality of memory dies DIE may include a plurality of memory blocks, and each of the plurality of memory blocks may include a plurality of memory cells. In one memory die DIE, an erase operation may be performed as a memory block unit.

The plurality of memory dies DIE may be connected to the storage controller 210 through a plurality of channels CH and a plurality of ways W. The memory dies DIE connected to one channel CH may perform a command and data communication in sequence through the one channel CH. However, the memory dies DIE each receiving a command may perform the command operation in parallel simultaneously.

The storage controller 210 may include a host interface 211, a memory interface 212, a processor 213, a buffer memory 214, and a packet manager 215. Also, the storage controller 210 may further include an access manager 216, a flash translation layer (FTL) 217, and a command analyzer 218.

The storage controller 210 may further include a working memory into which the FTL 217 is loaded, and data write and read operations for the nonvolatile memory may be controlled by the processor 213 executing the FTL 217.

The host interface 211 may transmit a packet to and receive a packet from the electronic control unit 100. A packet transmitted from the electronic control unit 100 to the host interface 211 may include a command or data to be written in the memory device 220, and a packet transmitted from the host interface 211 to the electronic control unit 100 may include a response to the command or data read from the memory device 220.

The memory interface 212 may transmit data to be written in the memory device 220 to the memory device 220, or may receive data read from the memory device 220. The memory interface 212 may be implemented to comply with a standard protocol such as Toggle or ONFI.

The processor 213 may execute the FTL 217, and may further execute the retention calculator 241, the retention checker 242 and the retention information generator 243 as described with reference to FIG. 2. The programs for executing the retention calculator 241, the retention checker 242 and the retention information generator 243 may be stored in the working memory.

The FTL 217 may perform several vehicle functions such as address mapping, wear-leveling, and garbage collection. The address mapping operation may be of changing a logical address received from a host into a physical address used to actually store data in the memory device 220. Wear-leveling may be a technique of preventing excessive deterioration of a specific block by ensuring that blocks in the memory device 220 are used uniformly, and may be implemented, for example, through firmware technology for balancing the erase counts of physical blocks. Garbage collection may be a technique of securing available capacity in the memory device 220 by copying valid data of a block to a new block and erasing the existing block.

The buffer memory 214 may temporarily store data to be written in the memory device 220, data to be read from the memory device 220, and metadata such as map data. The buffer memory 214 may be configured to be provided in the storage controller 210, or may also be disposed externally of the storage controller 210.

The packet manager 215 may generate a packet according to the protocol of the interface agreed upon with the electronic control unit 100, or may parse various information from a packet received from the electronic control unit 100.

The ECC engine 216 may perform an error detection and a correction function for read data read from the memory device 220. Specifically, the ECC engine 216 may generate parity bits for program data to be programmed in the memory device 220. The generated parity bits may be stored in the memory device 220 together with the program data. The ECC engine 216 may correct an error in the read data using parity bits read from the memory device 220 together with the read data, and may output the error-corrected read data.

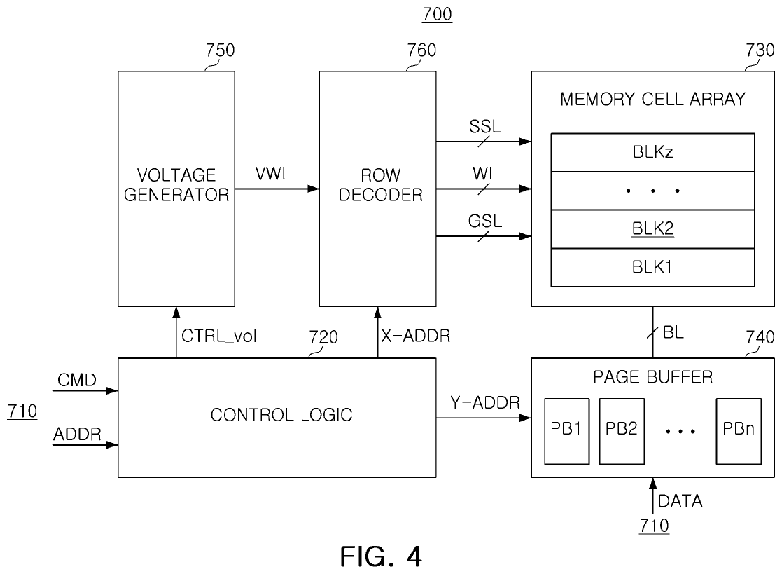

FIG. 4 is a diagram illustrating a memory device according to an example implementation.

The memory device 700 may correspond to the memory device 220 described with reference to FIG. 2 or the memory die DIE described with reference to FIG. 3. Referring to FIG. 4, the memory device 700 may include a control logic circuit 720, a memory cell array 730, a page buffer 740, a voltage generator 750, and a row decoder 760. The memory device 700 may further include a memory interface circuit 710, and may further include column logic, a pre-decoder, a temperature sensor, a command decoder, and an address decoder.

The control logic circuit 720 may generally control various operations in the memory device 700. The control logic circuit 720 may output various control signals in response to a command CMD and/or an address ADDR from the memory interface circuit 710. For example, the control logic circuit 720 may output a voltage control signal CTRL_vol, a row address X-ADDR, and a column address Y-ADDR.

The memory cell array 730 may include a plurality of memory blocks BLK1-BLKz (where z is a positive integer), and each of the plurality of memory blocks BLK1-BLKz may include a plurality of memory cells. The memory cell array 730 may be connected to the page buffer portion 740 through bitlines BL, and may be connected to the row decoder 760 through wordlines WL, string select lines SSL, and ground select lines GSL.

In an example implementation, the memory cell array 730 may include a three-dimensional memory cell array, and the three-dimensional memory cell array may include a plurality of NAND strings. Each NAND string may include memory cells each connected to wordlines vertically stacked on a substrate. U.S. Laid-Open Patent Publication No. 7,679,133, U.S. Laid-Open Patent Publication No. 8,553,466, U.S. Laid-Open Patent Publication No. 8,654,587, U.S. Laid-Open Patent Publication No. 8,559,235, and U.S. Laid-Open Patent Publication No. 2011/0233648 may be incorporated herein by reference. In an example implementation, the memory cell array 730 may include a two-dimensional memory cell array, and the two-dimensional memory cell array may include a plurality of NAND strings disposed in row and column directions.

The page buffer 740 may include a plurality of page buffers PB1-PBn (where n is an integer equal to or greater than 3), and the plurality of page buffers PB1-PBn may be connected to memory cells through a plurality of bitlines BL, respectively. The page buffer 740 may select at least one bitline among the bitlines BL in response to a column address Y-ADDR. The page buffer 740 may operate as a write driver or a sense amplifier depending on an operation mode. For example, during a program operation, the page buffer 740 may apply a bitline voltage corresponding to data to be programmed to the selected bitline. During a read operation, the page buffer 740 may sense data stored in the memory cell by sensing a current or voltage of the selected bitline.

The voltage generator 750 may generate various types of voltages for performing program, read, and erase operations based on a voltage control signal CTRL_vol. For example, the voltage generator 750 may generate a program voltage, a read voltage, a program verification voltage, and an erase voltage as a wordline voltage VWL.

The row decoder 760 may select one of a plurality of wordlines WL and one of a plurality of string select lines SSL in response to a row address X-ADDR. For example, the row decoder 760 may apply a program voltage and a program verification voltage to a selected wordline during a program operation, and may apply a read voltage to the selected wordline during a read operation.

Each of the memory cells included in the memory device 700 may be programmed to have one of a plurality of program states according to data to be programmed. Threshold voltages of the plurality of memory cells may form distribution.

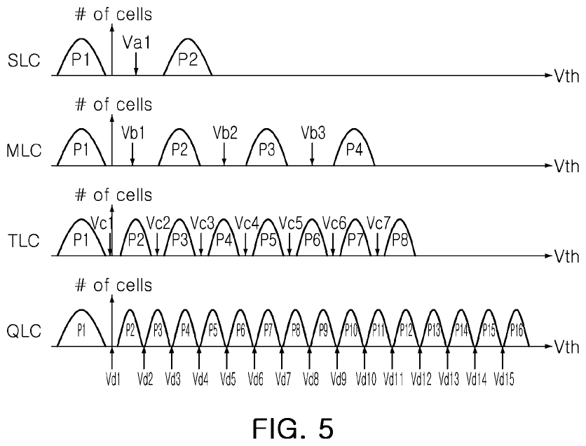

FIG. 5 is a diagram illustrating distribution of threshold voltage of memory cells according to an example implementation.

Referring to FIG. 5, distribution of threshold voltages of memory cells may be illustrated on a horizontal axis indicating a level of threshold voltage and a vertical axis indicating the number of memory cells.

When a memory cell is a single level cell (SLC) for storing 1 bit of data, the memory cell may have a threshold voltage corresponding to one of a first program state P1 or a second program state P2. The read voltage Val may be for distinguishing between the first program state P1 and the second program state P2. A memory cell having the first program state P1 may have a threshold voltage lower than the read voltage Val such that the memory cell may be read as an on-cell. A memory cell having the second program state P2 may have a threshold voltage higher than the read voltage Val such that the memory cell may be read as an off-cell.

When the memory cell is a multiple level cell (MLC) for storing 2 bits of data, the memory cell may have a threshold voltage corresponding to one of first to fourth program states P1-P4. The first to third read voltages Vbl-Vb3 may be read voltages for distinguishing the first to fourth program states P1-P4 from each other.

When the memory cell is a TLC (triple level cell) for storing 3 bits of data, the memory cell may have a threshold voltage corresponding to one first to eighth program states P1-P8. The first to seventh read voltages Vc1-Vc7 may be read voltages for distinguishing the first to eighth program states P1-P8 from each other.

When the memory cell is a quadruple level cell (QLC) for storing 4 bits of data, the memory cell may have one of first to sixteenth program states P1-P16. First to fifteenth read voltages Vdl-Vdl5 may be read voltages for distinguishing the first to sixteenth program states P1-P16 from each other.

The electric charge flowing into the programmed memory cells may drain over time after the memory cells are programmed, and the threshold voltage of the memory cells may be varied. As the number of data bits stored in a memory cell increases, an interval between the read voltages for distinguishing the program states may decrease. As the interval between the read voltages decreases, the risk of data loss due to the threshold voltage variation of the memory cells may increase.

In order for a high-capacity storage device to be applied to a vehicle system and for data integrity of the vehicle system to be retained, the vehicle system may be required to be able to retain the data of the storage device even in the powered-off state of the storage device. Hereinafter, a data retention method of the storage device according to an example implementation may be described.

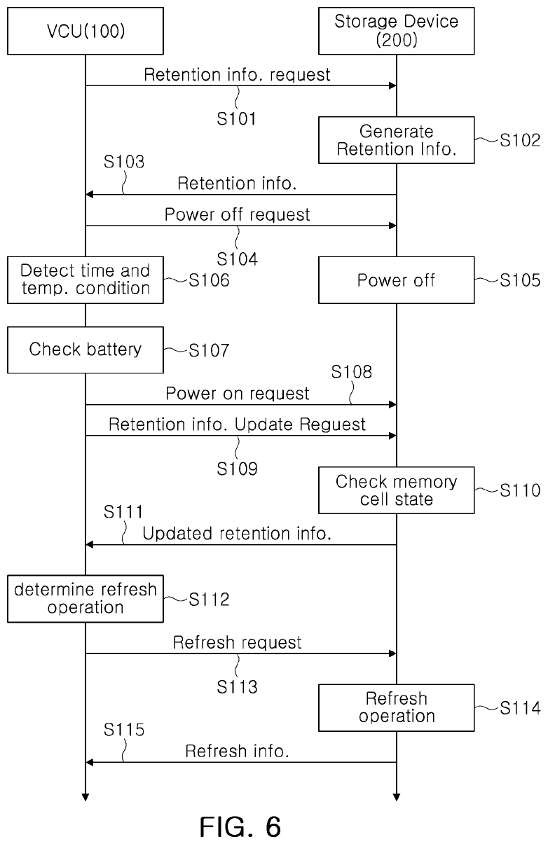

FIG. 6 is a diagram illustrating interaction between a vehicle control device and a storage device according to an example implementation.

The vehicle control unit 100 and the storage device 200 in FIG. 6 may correspond to the examples described with reference to FIGS. 1 to 3.

In operation S101, the vehicle control unit 100 may provide a retention information request to the storage device 200. For example, the vehicle control unit 100 may provide a retention information request to the storage device 200 when the operation termination of the vehicle is determined.

In operation S102, the storage device 200 may generate retention information. For example, the storage device 200 may obtain a temperature of an operation termination time point from the temperature sensor 230 described with reference to FIG. 1, may determine an initial retention expected period according to the temperature, and may generate retention information including the operation termination temperature and the initial retention expected period.

In operation S103, the storage device 200 may provide the retention information to the vehicle control unit 100 in response to the retention information request.

In operation S104, the vehicle control unit 100 may provide a power-off request to the storage device 200.

In operation S105, the storage device 200 may perform a power-off operation in response to the power-off request. The power-off operation may include a series of operations for safely terminating the storage device 200. For example, the power-off operation may include an operation for programming data buffered in the buffer memory 214 into the memory device 220.

When the operation of the vehicle is terminated, the storage device 200 may be powered off, and the vehicle control unit 100 may retain the powered-on state. For example, the vehicle control unit 100 may retain the powered-on state to monitor the state of the storage device 200 and the battery 600 while operation of the vehicle is terminated and the vehicle is parked.

In operation S106, the vehicle control unit 100 may sense a period condition or a temperature condition for updating the retention expected period based on a state of a memory cell of the storage device 200.

For example, the vehicle control unit 100 may configure the period condition such that the retention expected period may be updated before the initial retention expected period is reached. The vehicle control unit 100 may configure the temperature condition such that the retention expected period may be updated at a time point at which the temperature of the vehicle has significantly increased as compared to the operation termination time point of the storage device 200.

In operation S107, the vehicle control unit 100 may check residual capacity of the battery 600 of the vehicle system. The vehicle control unit 100 may control the storage device 200 to monitor a state of a memory cell when residual capacity of the battery 600 is sufficient in a state in which the period condition or the temperature condition is sensed.

In operation S108, the vehicle control unit 100 may provide a power-on request to the storage device 200. In operation S109, the vehicle control unit 100 may further provide a retention information update request to the storage device 200.

In operation S110, the storage device 200 may check a state of a memory cell in response to the retention information update request. For example, the storage device 200 may perform a read operation for a predetermined region of the memory device 220 and may check a state of a memory cell based on the read data.

According to an example implementation, the storage device 200 may update retention information, for example, a retention expected period, based on the checked cell state. The initial retention expected period may be determined based on the temperature of the storage device 200 at the operation termination time point. However, the storage device 200 may go through various temperature changes during the powered-off period, and the data retention state of the memory cells may be sensitive to the temperature. Accordingly, the updated retention expected period may be different from the retention expected period based on the initial retention expected period.

In operation S111, the storage device 200 may provide updated retention information to the vehicle control unit 100 in response to the retention expected period update request.

In operation S112, the vehicle control unit 100 may determine whether to perform a refresh operation of the storage device 200 based on the updated retention expected period. For example, when the updated retention expected period is a threshold period or less, the vehicle control unit 100 may provide a refresh request to the storage device 200 in operation S113. When the updated retention expected period is greater than the threshold period, the vehicle control unit may provide a power-off request to the storage device.

In operation S114, the storage device 200 may perform a refresh operation for memory regions of the memory device 220. For example, the storage device 200 may perform an operation of performing a read operation for a memory region, detecting and correcting an error in the read data, and storing the error-corrected data in another memory region on the entirety of memory regions in which data is programmed.

In operation S115, the storage device 200 may provide refresh information to the vehicle control unit 100 after the refresh operation is completed. The refresh information may include the period of the refresh operation and the amount of power of the battery 600 consumed due to the refresh operation.

According to an example implementation, the vehicle control unit 100 may request the storage device 200 to provide an updated retention expected period based on a state of a memory cell when a predetermined condition is sensed in the powered-off state of the storage device 200.

The vehicle control unit 100 may retain the storage device 200 in the powered-off state for most of the operation termination period of the vehicle, may also obtain an updated retention expected period by reflecting the temperature change of the storage device, and may control the refresh operation of the storage device 200 based on the updated retention expected period. Accordingly, the data of the vehicle system may be retained, and the battery consumption of the vehicle system may be saved.

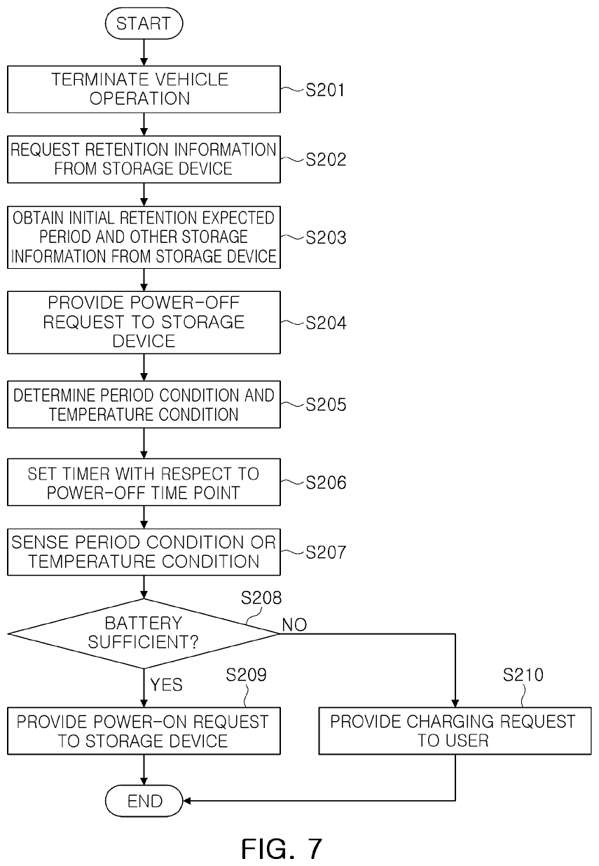

FIG. 7 is a diagram illustrating operation of a vehicle control device according to an example implementation.

In operation S201, the vehicle control unit may determine vehicle operation termination. The vehicle control unit may correspond to the vehicle control unit 100 described with reference to FIGS. 1 to 3.

In operation S202, the vehicle control unit may request retention information from the storage device.

In operation S203, the vehicle control unit may obtain retention information from the storage device. The storage device may correspond to the storage device 200 described with reference to FIGS. 1 to 3.

The retention information may include an operation termination temperature and an initial retention expected period. In an example implementation, the retention information may further include a usage rate of the storage device, P/E cycle of memory blocks, and firmware version information.

The vehicle control unit may store the retention information as retention information 121 in the memory 120 described with reference to FIG. 1.

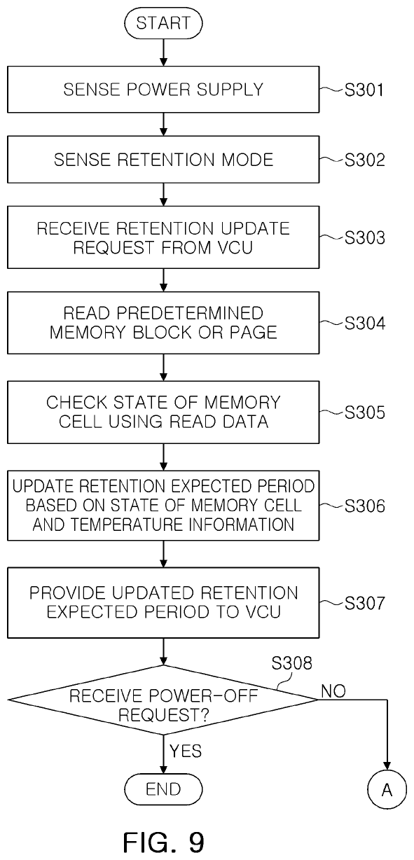

In operation S204, the vehicle control unit may provide a power-off request to the storage device. In an example implementation, the power-off request may be a retention mode power-off request for a retention mode of the storage device. The retention mode may be described later with reference to FIG. 9.

In operation S205, the vehicle control unit may determine a period condition and a temperature condition for updating a retention expected period.

The period condition may be determined based on a period calculated by multiplying an initial retention expected period of the storage device by a coefficient less than 1. For example, the vehicle control unit may determine a period corresponding to 30% of the retention expected period, a period corresponding to 50%, and a period corresponding to 70% as period conditions, respectively, and may sense whether the period condition is satisfied.

In an example implementation, the coefficient may be adjusted based on a usage rate of the storage device and a P/E cycle of memory blocks. The usage rate of the storage device may be determined as a ratio of capacity of the programmed data to total capacity of the storage device. For example, the vehicle control unit may monitor a state of a memory cell in a shorter period by adjusting the coefficient to a smaller value as the usage rate of the storage device increases and the P/E cycle of the memory blocks increases.

The temperature condition may be determined by adding a threshold temperature to the operation termination temperature. The vehicle control unit may monitor the present temperature using an external temperature sensor 301 as described with reference to FIG. 2, and may sense a condition in which the present temperature increases further than the temperature obtained by adding the threshold temperature to the operation termination temperature.

In operation S206, the vehicle control unit may set a timer 114 as described with reference to FIG. 2, and may monitor whether the period condition is satisfied. The vehicle control unit may further monitor whether the temperature condition is satisfied using an external temperature sensor 301 as described with reference to FIG. 2.

In operation S207, the vehicle control unit may sense a period condition or a temperature condition. For example, the vehicle control unit may detect whether the predetermined period condition or the predetermined temperature condition is satisfied.

In operation S208, the vehicle control unit may determine whether residual capacity of the battery of the vehicle system is sufficient using the battery checker 113 described with reference to FIG. 2. For example, the vehicle control unit may determine whether residual capacity of the battery is a threshold level or higher.

When the battery is sufficient (“YES” in operation S208), the vehicle control unit may provide a power-on request to the storage device in operation S209 such that the storage device may update the retention expected period.

When the battery is not sufficient (“NO” in operation S209), the vehicle control unit may provide a charging request to a user terminal in operation S210. For example, the vehicle control unit may generate a charging request message in a predetermined format using the message manager 115 as described with reference to FIG. 2, and may provide the charging request message to the user terminal through the telematics control unit 500.

The user may receive information related to the vehicle system using a vehicle management application installed in a user terminal. When the battery is not sufficient, the vehicle control unit may induce the user to charge the battery by providing a charging request message to the user terminal instead of providing a power-on request to the storage device.

Even when the vehicle control unit provides the charging request message to the user terminal, the battery may not be charged in a timely manner, such that data may be lost in the storage device. In an example implementation, when the data of the storage device is not able to be recovered, the vehicle control unit may reinstall firmware of the storage device using the firmware version information obtained in operation S203 and may reconfigure the storage device.

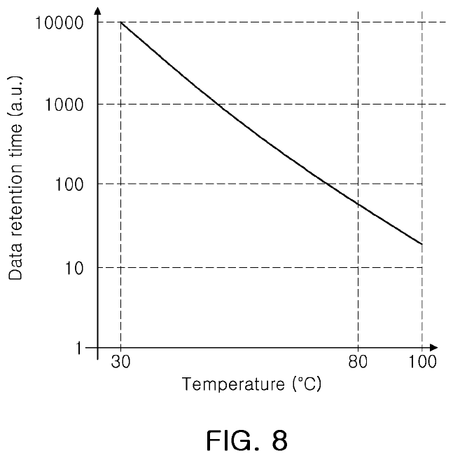

Hereinafter, a method of determining the initial retention expected period by the storage device may be described in detail with reference to FIG. 8.

FIG. 8 is a diagram illustrating a data retention period depending on a temperature according to an example implementation.

Referring to FIG. 8, a graph indicating a data retention period according to temperature may be drawn based on a horizontal axis indicating a temperature and a vertical axis indicating a data retention period in a log scale.

The data retention period of the storage device depending on the temperature of the storage device may be modeled based on the Arrhenius equation indicating the temperature dependence of the reaction speed. The Arrhenius equation is as below:

$$k = {Ae}^{\frac{- {E}_{a}}{RT}} \qquad [ Equation 1 ]$$

In equation 1, k may represent a velocity constant, T may represent an absolute temperature, A may represent an Arrhenius constant, Ea may represent an activation energy, and R may represent a gas constant. The value of the Arrhenius constant and the value of the activation energy may be determined according to reaction and may be determined experimentally. In the reaction in which the electric charge stored in the memory cells is released, the Arrhenius constant A, the activation energy Ea, and the gas constant R may be constants, and the velocity constant k of the reaction may be determined depending on the absolute temperature T. Accordingly, the data retention period due to the reaction may be determined depending on the absolute temperature T.

According to an example implementation, when the storage device receives a retention information request from a vehicle control unit, the storage device may determine a retention expected period based on the present temperature.

The data retention period of the storage device may be varied greatly depending on the temperature of the storage device. According to the Arrhenius equation, the data retention period of a storage device may decrease exponentially as the temperature of the storage device increases. For example, when the temperature of the storage device is 80° C., the data retention period may be 1/100 or less of the data retention period in which the temperature of the storage device is 30° C. When the data retention period is 1 year when the temperature of the storage device is 30° C., the data retention period may be only a few days when the temperature of the storage device is 80° C., and the data retention period may be only a few hours when the temperature of the storage device is 100° C.

A storage device applied to a vehicle system may experience various temperature changes in the powered-off state. For example, the storage device may retain the powered-off state during the operation termination period of the vehicle system. The vehicle system may be exposed to external temperatures fluctuating due to weather conditions during the parked period. Accordingly, the retention expected period determined based on the operation termination time point of the vehicle system and the retention expected period determined based on the data retention state of the memory cells during the operation termination period of the vehicle system may be different.

According to an example implementation, during a period in which the vehicle system is parked, the storage device may check a state of a memory cell in response to a request from the vehicle control unit and may update the retention expected period based on a state of a memory cell. Since the vehicle control unit or the storage device does not need to track the changing temperature of the vehicle system to determine the retention expected period, the power consumption of the battery may be reduced.

FIG. 9 is a diagram illustrating operation of a storage device according to an example implementation.

In operation S301, the storage device may sense the power supply. For example, the vehicle control unit may control the power of the battery to be supplied to the storage device when a predetermined period condition or a temperature condition is sensed and residual capacity of the battery is sufficient.

In operation S302, the storage device may sense the retention mode.

When the storage device senses or detects the power supply, the storage device may perform a series of operations to prepare operation of the storage device. For example, the storage device may perform an operation of loading programs stored in the memory device into the controller and initializing settings. The storage device may perform different power-on operations according to a predefined power mode. The power mode in which the storage device performs power-on operations may be determined when the storage device is powered off.

According to an example implementation, at least a normal mode and a retention mode may be defined as the power mode of the storage device. The power-on operation according to the normal mode may include operations of loading programs for various operations supported by the storage device and initializing settings. A power-on operation according to the retention mode may load a smaller number of programs and may initialize a smaller number of settings as compared to the normal mode in order to support a portion of operations of the storage device. For example, when the storage device is powered on according to the retention mode, the storage device may support a portion of operations such as an operation of checking a state of a memory cell, an operation of updating a retention expected period, and a refresh operation.

In operation S303, the storage device may receive a retention expected period update request from the vehicle control unit.

In operation S304, the storage device may read a predetermined memory block or a predetermined page. For example, the controller may provide a read request for a predetermined memory block or a predetermined page to the memory device and may obtain data read from the memory device.

A memory block or a page read to check a state of a memory cell may be experimentally determined in advance. For example, the memory block or page may be determined as a memory block or a page having electrical properties which may be vulnerable or which may represent other memory blocks and pages.

In operation S305, the storage device may check a state of a memory cell using the read data. For example, the storage device may determine a state of a memory cell by performing an off-cell count and an error bit count using the read data.

In operation S306, the storage device may update a retention expected period based on the state of the memory cell and temperature information.

For example, the storage device may store in advance a relationship model of an estimated left period for a state of a memory cell at a predetermined test temperature. The left period may refer to a period during which a memory cell is not refreshed after being programmed. The storage device may store a relationship model of a retention expected period for a temperature described with reference to FIG. 8. The storage device may determine an estimated left period at a temperature of a power-off time point based on a state of a memory cell determined. The storage device may determine an updated retention expected period by subtracting the estimated left period from the initial retention expected period.

In operation S307, the storage device may provide the updated retention expected period to the vehicle control unit.

In operation S308, the storage device may determine whether to receive a power-off request. For example, when the vehicle control unit determines that a refresh operation of the storage device may not be necessary based on the updated retention expected period, the vehicle control unit may provide the power-off request to the storage device.

As described with reference to operation S111 in FIG. 6, the vehicle control unit may receive an updated retention expected period from the storage device, may determine whether to perform a refresh operation of the storage device based on the updated retention expected period, and may selectively provide a refresh request or a power-off request.

In example implementations, the vehicle control unit is not limited to determining whether to perform a refresh operation of the storage device. For example, the storage device may determine an updated retention expected period and may also determine whether to perform a refresh operation based on the updated retention expected period.

When a power-off request is received (in operation S308, “YES”), the storage device may terminate the operation.

When the power-off request is not received (in operation S308, “NO”), the storage device may perform operation S401 in FIG. 12.

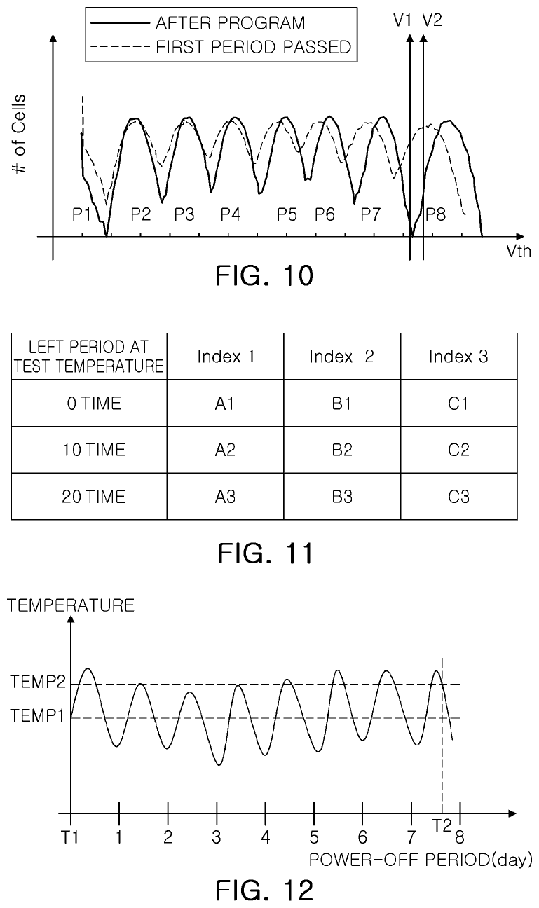

Hereinafter, a state of a memory cell checking method and a retention period updating method of a storage device may be described in detail with reference to FIGS. 10 and 11.

FIG. 10 is a diagram illustrating a memory cell state checking method according to an example implementation.

FIG. 10 illustrates a distribution of threshold voltage of memory cells. Specifically, FIG. 10 illustrates the number (# of Cells) of memory cells according to threshold voltage Vth state immediately after memory cells are programmed and after a first period has passed after the memory cells are programmed. In the example in FIG. 10, memory cells may have eight program states P1-P8.

As time passes after memory cells are programmed, a threshold voltage of memory cells may decrease as electric charges stored in the memory cells are discharged. In the example in FIG. 10, the distribution of threshold voltage of the memory cells may shift to the left after the first period has passed as compared to immediately after being programmed.

In an example implementation, the controller may control the memory device to read a predetermined region using the first read voltage V1 and the second read voltage V2, and may check a state of a memory cell by counting the number of memory cells of which the threshold voltage is in the range of the first read voltage V1 to the second read voltage V2 using the read data.

The first read voltage V1 to the second read voltage V2 may be experimentally determined in advance. For example, as time passes after the memory cells are programmed, distribution of threshold voltage may shift most significantly in the eighth program state P8 having the highest threshold voltage. That is, the threshold voltage of the memory cells having the eighth program state P8 may change most sensitively depending on the state of a memory cell. Accordingly, the first read voltage V1 to the second read voltage V2 may be determined based on the threshold voltage range of the eighth program state P8.

In an example implementation, the controller may control the memory device to read a predetermined region using a read voltage, and may check a state of a memory cell by counting off-cells having a threshold voltage higher than the read voltage using the read data.

In an example implementation, the controller may also check a state of a memory cell by controlling the memory device to read a specific number of data bits among data bits stored by each of the memory cells, may detect and correct error bits of the read data using an ECC engine, and may perform an error bit count. For example, when a memory cell stores three data bits of an MSB (most significant bit), a CSB (central significant bit), and an LSB (least significant bit), the controller may control the memory device to read MSB data from each of the memory cells of the predetermined memory region using a portion of read voltages, may perform detection and correction of an error of the MSB data, and may perform an error bit count of the MSB data.

FIG. 11 is a diagram illustrating a retention period updating method according to an example implementation.

FIG. 11 may illustrate a table indicating a first index to a third index related to a state of a memory cell according to a left period at a test temperature of a storage device. For example, the first index may be the number of memory cells included in a first threshold voltage range between the first read voltage V1 and the second read voltage V2 in FIG. 10, the second index may be the number of off-cells having a threshold voltage higher than the first read voltage V1, and the third index may include the number of error bits of MSB data.

The table in FIG. 11 may be experimentally determined in advance. For example, the storage device may be left in a state in which data is programmed at a predetermined test temperature. The storage device may periodically read data at the test temperature and may determine the first to third indices of the read data.

For example, the actual values of the first index, the second index, and the third index may be determined based on the data read immediately after the data is programmed, after 10 hours, and after 20 hours at a predetermined test temperature. A1, A2, and A3 in FIG. 11 may indicate the actual values of the first index, B1, B2, and B3 may indicate the actual values of the second index, and C1, C2, and C3 may indicate the actual values of the third index.

The storage device may use a state of a memory cell model according to a left period determined based on the table in FIG. 11 or a state of a memory cell model according to the left period determined based on the table. In an example implementation, a state of a memory cell model may be determined using at least one index from the first index to the third index.

For example, the storage device may count the number of error bits of MSB data using the read data, and may determine a left period corresponding to the number of error bits by referring to the table. The storage device may determine an updated retention expected period at a threshold temperature.

The storage device may convert a left period at a test temperature into an estimated left period at a temperature at an operation termination time point using a relationship model of data retention periods according to temperature as described with reference to FIG. 8. The storage device may determine an updated retention expected period by subtracting the estimated left period from the initial expected retention time at the temperature of the operation termination time point.

For example, the initial retention expected period at the temperature of the operation termination time point may be 12 months, and after 3 months from the power off of the storage device, the storage device may be powered on and may check a state of a memory cell. As a result of calculating the estimated left period using the state of the memory cell, the relationship model of a state of a memory cell according to the left period, and the relationship model of the data retention time according to the temperature by the storage device, it may be determined that the present state of the memory cell may correspond to a state in which the memory cell is left at a threshold temperature for 7 months. In this case, the storage device may update the retention expected period to 5 months by subtracting the left period of 7 months from the initial retention expected period of 12 months.

Even when a state of a memory cell is the same, the retention expected period may be determined by a different value depending on the reference temperature. The updated retention expected period may be determined based on the temperature of the operation termination time point, but an example implementation thereof is not limited thereto. In an example implementation, the reference temperature for determining the updated retention expected period may be selectively updated.

Hereinafter, a method for determining the reference temperature for determining the updated retention expected period by the storage device according to an example implementation may be described.

FIG. 12 is a diagram illustrating a temperature of a vehicle depending on a power-off period of a storage device according to an example implementation.

FIG. 12 may illustrate a graph indicating temperature according to a power-off period of a storage device. During the power-off period of the storage device applied to a vehicle system, memory cells of the storage device may go through various temperature changes. For example, when a vehicle system is parked for several days, the temperature of the storage device may change periodically due to the daily temperature difference.

FIG. 12 may illustrate a first temperature TEMP1 of a first time point T1, which is an operation termination time point of a storage device, and a second temperature TEMP2 of a second time point T2, which is a state of a memory cell check time point. According to an example implementation, an initial retention expected period may be determined based on the first temperature TEMP1. A state of a memory cell determined at the second time point T2 may reflect influence of temperature changes at both the first time point T1 and the second time point T2.

According to an example implementation, a reference temperature for determining an estimated left period based on the state of the memory cell and determining an updated retention expected period may be determined based on the first temperature TEMP1 and the second temperature TEMP2.

According to an example implementation, the reference temperature may be determined as a higher temperature among the first temperature TEMP1 and the second temperature TEMP2. For example, when the second temperature TEMP2 is higher than the first temperature TEMP1, the storage device may determine an estimated left period and update an initial retention expected period based on the second temperature TEMP2, and may determine an updated retention expected period by subtracting the estimated left period from the updated initial retention expected period. When the second temperature TEMP2 is lower than the first temperature TEMP1, the storage device may determine an estimated left period and an initial retention expected period based on the first temperature TEMP1, and may determine an updated retention expected period by subtracting the estimated left period from the initial retention expected period.

The storage device may conservatively determine the updated retention expected period in a temperature-varying environment by determining the higher temperature among the first temperature TEMP1 and the second temperature TEMP2 as a reference temperature. Accordingly, a refresh operation may be performed before data of the storage device is lost in a temperature-varying environment.

Hereinafter, a refresh operation method of the storage device may be described in detail.

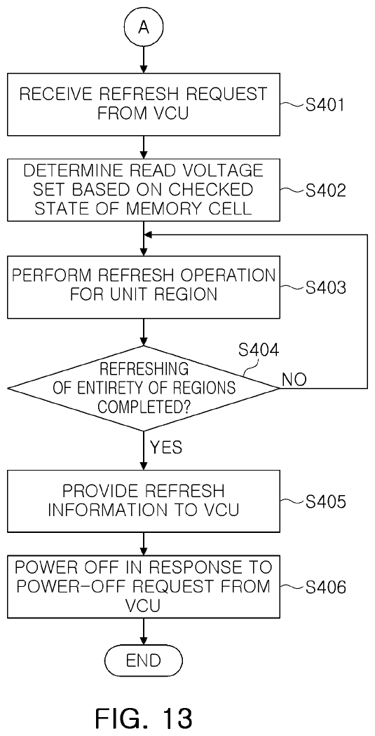

FIG. 13 is a diagram illustrating operation of a storage device according to an example implementation.

In operation S308 in FIG. 9, when the storage device does not receive a power-off request from the vehicle control unit (“NO” in operation S308), operation S401 in FIG. 13 may be performed.

In operation S401, the storage device may receive a refresh request from the vehicle control unit.

In an example implementation, instead of receiving a refresh request from the vehicle control unit, the storage device may determine whether to perform a refresh operation based on the updated retention expected period.

In operation S402, the storage device may determine a read voltage set for performing the refresh operation based on a state of a memory cell determined in operation S305. The read voltage set may include voltage levels of one or more read voltages for distinguishing program states of the memory cell.

For example, the storage device may select a read voltage set including read voltages of lower levels as the off-cell count decreases from a predetermined threshold voltage among a plurality of read voltage sets. According to an example implementation, a read voltage set corresponding to a present state of a memory cell may be determined using a state of a memory cell determined to update a retention expected period, thereby reducing trial and error for determining a read voltage set and improving reliability of read data.

In operation S403, the storage device may perform a refresh operation for a unit region. For example, the unit region may be a page. The storage device may determine read data by applying read levels included in the read voltage set to a wordline corresponding to a page, and obtaining data corresponding to each read level. The storage device may detect and correct errors in the read data by performing ECC decoding, and may perform a refresh operation to program the error-corrected data to another unit region.

In operation S404, the storage device may determine whether the refreshing of the entirety of regions programmed with data is completed. When the refreshing of the entirety of regions is not completed (“NO” in operation S404), the storage device may repeatedly perform operation S403 and operation S404. When the refresh of the entirety of regions is completed (“YES” in operation S404), the storage device may perform operation S405.

In operation S405, the storage device may provide refresh information to the vehicle control unit. In an example implementation, the refresh information may include a period of time required for the refresh operation and power consumed for the refresh operation. The refresh information may be collected by the vehicle control unit and may be analyzed using machine learning.

In operation S406, the storage device may perform a power-off operation in response to a power-off request from the vehicle control unit.

According to an example implementation, during an operation termination period of a vehicle system, a storage device may be powered on in a limited manner to update a retention expected period and to perform a refresh operation, and may be powered off in the remaining period. Particularly, whether to perform a refresh operation involving a read operation and a program operation for the entirety of programmed regions of a memory device may be selected based on the updated retention expected period, such that unnecessary power consumption of a battery may be prevented.

As described with reference to FIG. 9, a retention mode may be defined in which the storage device updates a retention expected period and executes a limited function to perform a refresh operation. In an example implementation, a vehicle control unit may predict whether a vehicle is long-term parked, and may determine a power mode of the storage device as a retention mode or a normal mode based on whether the vehicle is long-term parked.

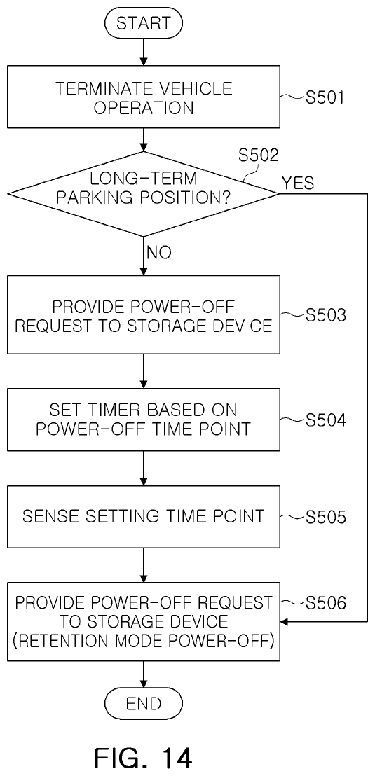

FIG. 14 is a diagram illustrating operation of a vehicle control device according to an example implementation.

In operation S501, the vehicle control unit may determine vehicle operation termination.

In operation S502, the vehicle control unit may determine whether the position at which the vehicle operation is terminated is a long-term parking position.

In an example implementation, the vehicle control unit may determine the position at which the vehicle operation is terminated by receiving a GPS signal through an antenna 501 as described with reference to FIG. 1.

In an example implementation, the vehicle control unit may collect a parking period according to the parking position of the vehicle, and may determine whether the position at which the vehicle operation is terminated is a long-term parking position based on the collected parking period.

In an example implementation, the vehicle control unit may determine whether the position at which the vehicle operation is terminated is a long-term parking position based on information input from a user terminal. For example, a vehicle management application installed on a user terminal may provide a user interface for registering long-term parking positions, such as a home and office of a user, and may transmit the long-term parking positions to the vehicle control unit.

When the position at which the vehicle operation is terminated is a long-term parking position (in operation S502, “YES”), the vehicle control unit may provide a retention mode power-off request to the storage device in operation S506. Although omitted in FIG. 14, the vehicle control unit may obtain retention information from the storage device before providing the retention mode power-off request. According to an example implementation, the vehicle control unit may effectively retain data while reducing power consumption in a space in which the vehicle is predicted to be parked for a long period of time.

When the position at which the vehicle operation is terminated is a short-term parking position (in operation S502, “NO”), the vehicle control unit may provide a normal mode power-off request to the storage device in operation S503. According to an example implementation, the vehicle control unit may swiftly return to the normal operation state by controlling the storage device to be powered on in a normal mode in a space in which the vehicle is predicted to be parked for a short period of time, such as a mart or a gas station.

In operation S504, the vehicle control unit may set a timer based on the power-off time of the storage device. The setting time point of the timer may be a time point for determining whether the vehicle is long-term parked in a short-term parking position, and may be independent of a period condition determined based on a retention expected period according to an example implementation.

In operation S505, the vehicle control unit may detect the setting time point of the timer. When the setting time point of the timer is sensed, the vehicle control unit may provide a power-on request to the storage device and may provide a retention mode power-off request in operation S506. That is, when the vehicle is parked in a short-term parking position for a relatively long period of time, the vehicle control unit may effectively retain data by switching the power mode from a normal mode to a retention mode.

According to the aforementioned example implementations, the vehicle control unit, the storage device, and the vehicle system may control performing of a refresh operation by the storage device by reflecting the temperature history actually gone through by memory cells while the storage device is powered off.

Also, the vehicle control unit, the storage device and the vehicle system may reduce power consumption of a vehicle battery by preventing data loss of the storage device and preventing refresh operations from being excessively frequently performed on the storage device.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A vehicle control device, comprising:
a memory configured to store a vehicle control program; and
a processor configured to execute the vehicle control program to:
receive, in response to a detection of an operation termination of a vehicle, an initial retention expected period from a storage device of the vehicle;
provide a power-off request to the storage device;
detect a period condition or a temperature condition before the initial retention expected period has elapsed and after the power-off request is provided to the storage device;
provide a power-on request to the storage device in response to a residual capacity of a battery of the vehicle being equal to or exceeding a threshold level;
control the storage device to check a state of a memory cell of a predetermined memory region of the storage device;
receive an updated retention expected period based on the state of the memory cell of the predetermined memory region of the storage device; and
selectively provide a refresh request to the storage device based on the updated retention expected period.

2. The vehicle control device of claim 1, wherein the processor is configured to determine the period condition by adding a period to a power-off time point of the storage device, wherein the period is determined by multiplying the initial retention expected period by a coefficient less than 1.

3. The vehicle control device of claim 2, wherein the processor is configured to further receive a usage rate and a program/erase (P/E) cycle information of the storage device from the storage device in response to the detection of the operation termination of the vehicle, and to determine a value of the coefficient based on the usage rate and the P/E cycle information.

4. The vehicle control device of claim 1, wherein the processor is configured to receive an operation termination temperature from the storage device in response to the detection of the operation termination of the vehicle, and to determine the temperature condition by adding a threshold temperature to the operation termination temperature.

5. The vehicle control device of claim 1, wherein the processor is configured to provide the refresh request to the storage device in response to the updated retention expected period being equal to or less than a threshold period.

6. The vehicle control device of claim 1, wherein the processor is configured to provide a power-off request to the storage device in response to the updated retention expected period being greater than a threshold period.

7. The vehicle control device of claim 1, wherein the processor is configured to output a message to a user terminal in response to the residual capacity of the battery of the vehicle being less than the threshold level.

8. The vehicle control device of claim 1, wherein the processor is configured to receive a result of a refresh operation from the storage device and to store the result of the refresh operation.

9. The vehicle control device of claim 1, wherein the initial retention expected period is determined based on a temperature of the storage device at an operation termination time point.

10. A storage device, comprising:
a memory device configured to store data of a vehicle; and
a controller configured to control the memory device,
wherein the controller is configured to:
determine, in response to a retention expected period request, an initial retention expected period based on a first temperature of the storage device at an operation termination time point of the vehicle;
provide the first temperature and the initial retention expected period to a vehicle control device;
perform a power-off operation in response to a power-off request;
perform an initialization operation in response to a power-on request;
perform a read operation on a predetermined memory region in response to an update request for a retention expected period;
determine a state of a memory cell of the storage device based on a result of the read operation;
determine an updated retention expected period based on the determined state of the memory cell and a temperature of the storage device; and
selectively perform a refresh operation based on the updated retention expected period.

11. The storage device of claim 10, comprising:
a temperature sensor,
wherein the controller is configured to obtain the first temperature from the temperature sensor, and to determine the initial retention expected period based on the first temperature and a relationship model between a temperature and a retention expected period.

12. The storage device of claim 11, wherein in response to a second temperature at a second time point at which the state of the memory cell is determined being higher than the first temperature, the controller is configured to:
determine an estimated left period based on the second temperature, the determined state of the memory cell and a relationship model between a state of a memory cell and a left period at a test temperature;
modify the initial retention expected period based on the second temperature; and
determine the updated retention expected period by subtracting the estimated left period from the modified initial retention expected period.

13. The storage device of claim 11, wherein in response to a second temperature at a second time point at which the state of the memory cell is determined being smaller than the first temperature, the controller is configured to:
determine an estimated left period based on the first temperature, the determined state of the memory cell and a relationship model between a state of a memory cell and a left period at a test temperature; and
determine the updated retention expected period by subtracting the estimated left period from the initial retention expected period.

14. The storage device of claim 10, wherein the controller is configured to control the memory device to perform the read operation by applying a predetermined first read voltage to the predetermined memory region, and to determine the state of the memory cell by counting a number of off-cells based on data read from the memory device.

15. The storage device of claim 10, wherein the controller is configured to control the memory device to perform the read operation by applying predetermined first and second read voltages to the predetermined memory region, and to determine the state of the memory cell by counting a number of memory cells having a threshold voltage between the first read voltage and the second read voltage based on data read from the memory device.

16. The storage device of claim 10,
wherein the memory device includes a plurality of memory cells, and each of the plurality of memory cells is configured to store a plurality of bits of data, and
wherein the controller is configured to control the memory device to read a first bit of the plurality of bits of data from each of the plurality of memory cells using at least one of a plurality of read voltages, to perform detection and correction of an error of the first bit of the plurality of bits of data, and to determine the state of the memory cell by counting a number of error bits of the first bit of the plurality of bits of data.

17. The storage device of claim 10, wherein, in response to the refresh operation being completed, the controller is configured to output a time taken for the refresh operation and an amount of power consumed due to the refresh operation.

18. The storage device of claim 10, wherein the controller is configured to perform the refresh operation by determining a read voltage set for the memory device based on the state of the memory cell, performing the read operation on memory regions of the memory device using the read voltage set, correcting errors in data read from the memory regions, and storing error-corrected data in the memory device.

19. A vehicle system, comprising:
a storage device configured to store vehicle data; and
a vehicle control device configured to execute a vehicle control program,
wherein the vehicle control device is configured to detect a parking position in response to a vehicle operation being terminated; in response to long-term parking of a vehicle being predicted based on the parking position, to receive an initial retention expected period determined based on a temperature of the storage device from a storage device mounted on the vehicle; to provide a first power-off request for a retention mode to the storage device; to detect a period condition or a temperature condition before the initial retention expected period has elapsed after the first power-off request is provided; and to provide a power-on request to the storage device in response to a detection of the period condition or the temperature condition, and
wherein the storage device is configured to control a read operation on a predetermined memory region in response to power being supplied and the retention mode being detected, and to provide an updated retention expected period that is determined based on a cell state and a temperature of the storage device, the cell state being determined based on the read operation from the storage device.

20. The vehicle system of claim 19,
wherein the vehicle control device is configured to provide a second power-off request for a normal mode to the storage device in response to short-term parking of the vehicle being predicted based on the parking position, and
wherein the storage device is configured to perform an initialization operation in response to power being supplied and the normal mode being detected.
